(19) United States
(12) Patent Application Publication
(10) Pub. No.: US 2024/0372325 A1
(43) Pub. Date: Nov. 7, 2024

(54) VARIABLE-WAVELENGTH LASER

(71) Applicant: SUMITOMO ELECTRIC DEVICE INNOVATIONS, INC., Yokohama-shi, Kanagawa (JP)

(72) Inventor: Noriaki KAIDA, Yokohama-shi (JP)

(73) Assignee: SUMITOMO ELECTRIC DEVICE INNOVATIONS, INC., Yokohama-shi, Kanagawa (JP)

(21) Appl. No.: 18/552,586

(22) PCT Filed: Mar. 31, 2022
(86) PCT No.: PCT/JP2022/016713

§ 371 Date: Sep. 26, 2023

(30) Foreign Application Priority Data
Mar. 31, 2021 (JP) 2021-061343

(51) Int. Cl. H01S 5/12; H01S 5/026; H01S 5/06; H01S 5/50

(52) U.S. Cl. CPC H01S 5/12; H01S 5/0265; H01S 5/0612; H01S 5/50

(57) ABSTRACT

A variable-wavelength laser includes a gain region and a wavelength control region alternately arranged along a propagation direction of light, a diffraction grating arranged in each of the gain region and the wavelength control region, and a region located at least one of an end of the gain region and an end of the wavelength control region at a boundary between the gain region and the wavelength control region, the region being without the diffraction grating, wherein a length of the region without the diffraction grating is 5% or more and 30% or less of a length of the gain region or the wavelength control region to which the region belongs.

### TECHNICAL FIELD

The present disclosure relates to a variable-wavelength laser.

### BACKGROUND

There is known a variable-wavelength laser having a gain function for laser oscillation and a wavelength control function as an optical device. For example, regions having a gain and regions for wavelength control are alternately arranged in a laser element (PTL 1, etc.).

### PRIOR ART DOCUMENT

### Patent Literature

PTL 1: Japanese Unexamined Patent Application Publication No. 4-147686

### SUMMARY OF INVENTION

A variable-wavelength laser according to the present disclosure includes a gain region and a wavelength control region alternately arranged along a propagation direction of light, a diffraction grating arranged in each of the gain region and the wavelength control region, and a region located at least one of an end of the gain region and an end of the wavelength control region in a boundary between the gain region and the wavelength control region, the region being without the diffraction grating, wherein a length of the region without the diffraction grating is 5% or more and 30% or less of a length of the gain region or the wavelength control region to which the region belongs

### BRIEF DESCRIPTION OF THE DRAWINGS

FIG. 1 is a plan view illustrating a variable-wavelength laser according to a first embodiment.

FIG. 2 is a cross-sectional view taken along line A-A of FIG. 1.

FIG. 3 is an enlarged view of a gain region and a wavelength control region.

FIG. 4 is a cross-sectional view taken along line B-B of FIG. 3.

FIG. 5 is a cross-sectional view taken along line C-C of FIG. 3.

FIG. 6A is a cross-sectional view illustrating a method of manufacturing a variable-wavelength laser.

FIG. 6B is a cross-sectional view illustrating a method of manufacturing a variable-wavelength laser.

FIG. 6C is a cross-sectional view illustrating a method of manufacturing a variable-wavelength laser.

FIG. 7A is a cross-sectional view illustrating a method of manufacturing a variable-wavelength laser.

FIG. 7B is a cross-sectional view illustrating a method of manufacturing a variable-wavelength laser.

FIG. 7C is a cross-sectional view illustrating a method of manufacturing a variable-wavelength laser.

FIG. 8 is a cross-sectional view illustrating a variable-wavelength laser according to a comparative example.

FIG. 9A is a spectrum of a reflectance.

FIG. 9B is a spectrum of a reflectance.

FIG. 9C is a spectrum of a reflectance.

FIG. 10A is a spectrum of a reflectance.

FIG. 10B is a spectrum of a reflectance.

FIG. 10C is a spectrum of a reflectance.

FIG. 10D is a spectrum of a reflectance.

FIG. 11 is a diagram illustrating a relationship between the length of a region and the heights of peaks.

FIG. 12A is an enlarged view of a diffraction grating layer, an active layer and a wavelength control layer.

FIG. 12B is an enlarged view of a diffraction grating layer, an active layer and a wavelength control layer.

FIG. 13 is a cross-sectional view illustrating a variable-wavelength light source.

FIG. 14A is a spectrum of a reflectance.

FIG. 14B is a spectrum of a reflectance.

FIG. 14C is a spectrum of a reflectance.

FIG. 15 a diagram illustrating a relationship between the length of a region and the heights of peaks.

FIG. 16 is a cross-sectional view illustrating a variable-wavelength light source.

FIG. 17A is a spectrum of a reflectance.

FIG. 17B is a spectrum of a reflectance.

FIG. 17C is a spectrum of a reflectance.

FIG. 18 is a diagram illustrating a relationship between the length of a region and the heights of peaks.

### DETAILED DESCRIPTION

### Problem to be Solved by Present Disclosure

Light occurs by injecting a current into a gain region. An oscillation wavelength is changed by injecting a current into a wavelength control region and changing a refractive index. When the refractive index of the wavelength control region is significantly different from that of the gain region, a so-called mode hop in which light oscillates at a wavelength different from a desired wavelength may occur. An amount of change in the refractive index of the wavelength control region in which the mode hop occurs differs depending on a structure of the laser and a semiconductor material. Therefore, it is an object of the present disclosure to provide a variable-wavelength laser capable of suppressing the mode hop.

### Effect of the Present Disclosure

According to the present disclosure, it is possible to provide a variable-wavelength laser capable of suppressing a mode hop.

### Description of Embodiments of the Present Disclosure

First, the contents of embodiments of the present disclosure will be listed and explained.
(1) A variable-wavelength laser according to an aspect of the present disclosure includes a gain region and a wavelength control region alternately arranged along a propagation direction of light, a diffraction grating arranged in each of the gain region and the wavelength control region, and a region located at least one of an end of the gain region and an end of the wavelength control region in a boundary between the gain region and the wavelength control region, the region being without the diffraction grating, wherein a length of the region without the diffraction grating is 5% or more and 30% or less of a length of the gain region or the wavelength control region to which the region belongs. With this configuration, a mode hop can be suppressed.
(2) A number of regions without the diffraction grating may be 70% or more of a total number of boundaries between the gain region and the wavelength control region.
(3) The region without the diffraction grating may be arranged at a most end of the gain region or the wavelength control region.
(4) The length of the region without the diffraction grating may be 10% or more and 25% or less of the length of the gain region or the wavelength control region to which the region belongs.
(5) The length of the region without the diffraction grating may be 15% or more and 20% or less of the length of the gain region or the wavelength control region to which the region belongs.
(6) The variable-wavelength laser further may include an optical modulator optically coupled to the gain region and the wavelength control region.
(7) A variable optical attenuator may be arranged between the optical modulator, and the gain region and the wavelength control region.
(8) A semiconductor optical amplifier may be arranged at an output of the optical modulator.
(9) A refractive index of the wavelength control region may be controlled by current injection.
(10) A refractive index of the wavelength control region may be controlled by a heater.
(11) The region without the diffraction grating may be arranged at both ends of any one of the gain region and the wavelength control region.
(12) The region without the diffraction grating may be arranged at both ends of both the gain region and the wavelength control region.
(13) The region without the diffraction grating may be arranged only at one end of any one of the gain region and the wavelength control region.

### Details of Embodiments of Present Disclosure

Specific examples of the variable-wavelength laser according to embodiments of the present disclosure will be described below with reference to the drawings. The present disclosure is not limited to these examples, and is defined by the scope of the claims, and is intended to include all modifications within the meaning and scope equivalent to the scope of the claims.

### First Embodiment

### (Variable-Wavelength Laser)

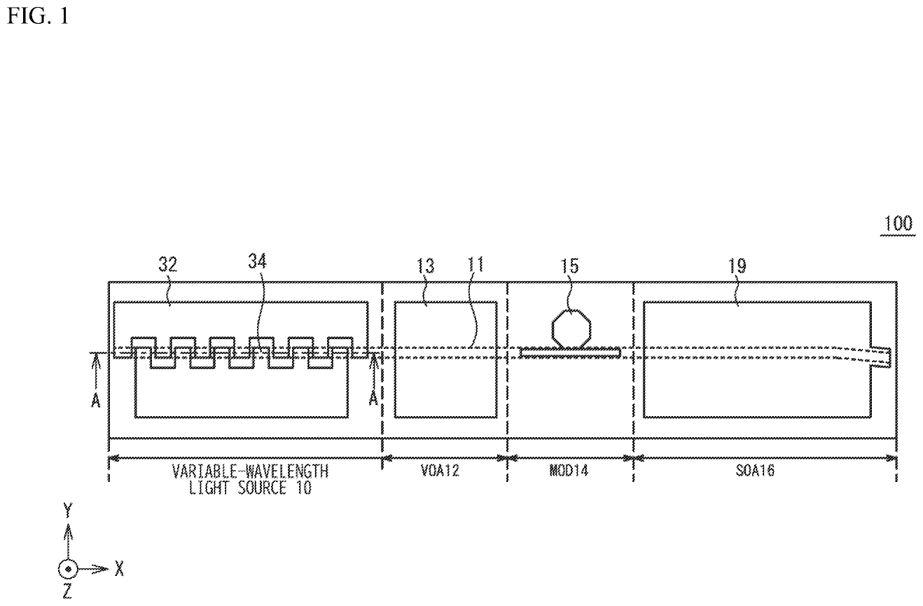

FIG. 1 is a plan view illustrating a variable-wavelength laser 100 according to a first embodiment. As illustrated in FIG. 1, the variable-wavelength laser 100 is an electro-absorption modulator integrated laser (EML: Electro-Absorption Modulator Laser Diode) including a variable-wavelength light source 10, a variable optical attenuator (VOA: variable optical attenuator) 12, a modulator (MOD: Modulator) 14, and a semiconductor optical amplifier (SOA: Semiconductor Optical Amplifier) 16. The variable wavelength light source 10 is optically coupled to the VOA 12, the MOD 14, and the SOA 16. An XY plane is a direction in which an upper surface of the variable-wavelength laser 100 spreads. An X-axis direction is an extending direction of an optical waveguide 11 and a propagation direction of light. A Y-axis direction is perpendicular to the X-axis direction. A Z-axis direction is a thickness direction of the variable-wavelength laser 100, and is perpendicular to the X-axis direction and the Y-axis direction. The length of the variable-wavelength laser 100 in the Y-axis direction is, for example, 250 μm. The length of the variable-wavelength light source 10 in the X-axis direction is, for example, 520 μm.

As illustrated in FIG. 1, the variable-wavelength light source 10, the VOA 12, the MOD 14, and the SOA 16 include the optical waveguide 11 and are arranged in this order along the extending direction of the optical waveguide 11. Electrodes 13, 15, 19, 32 and 34 are provided on the upper surface of the variable-wavelength laser 100. The electrodes 32 and 34 are provided in the variable-wavelength light source 10. The electrode 13 is provided in the VOA12. The electrode 15 is provided in the MOD 14. The electrode 19 is provided in the SOA 16. The electrodes 13, 15, 19, 32 and 34 are seperated from each other. A distance between the electrode 32 and the electrode 34 in the Y-axis direction is, for example, 10 μm. A distance in the X-axis direction is, for example, 7 μm. An anti-reflection layer (AR) film may be provided at both ends in the X-axis direction of the variable-wavelength laser 100. The AR layer has, for example, a two layer structure of titanium oxynitride (TiON) and titanium dioxide (TiO₂), or a two layer structure of aluminum oxide (Al₂O₃) and titanium dioxide.

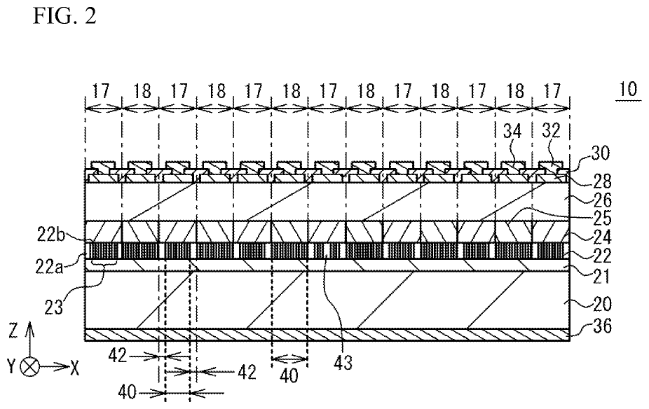

FIG. 2 is a cross-sectional view taken along line A-A of FIG. 1 and illustrates the variable-wavelength light source 10. As illustrated in FIG. 2, the variable-wavelength light source 10 includes a plurality of gain regions 17 and a plurality of wavelength control regions 18. Here, each of the gain region 17 and the wavelength control region 18 indicates a region extending over the entire thickness direction of the variable-wavelength light source 10. The number of gain regions 17 is, for example, seven. The number of wavelength control regions 18 is six, for example. The plurality of gain regions 17 and the plurality of wavelength control regions 18 are alternately arranged along the propagation direction of light (X-axis direction). The gain regions 17 are located at both ends of the variable-wavelength light source 10 in the X-axis direction.

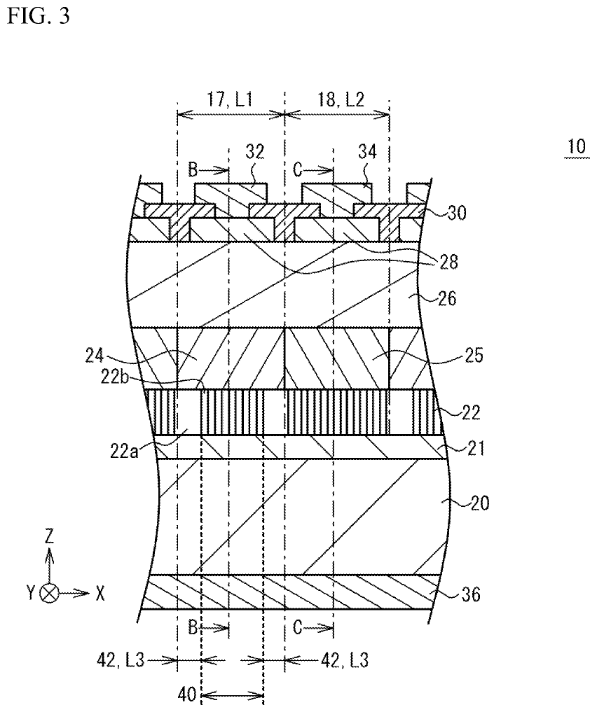

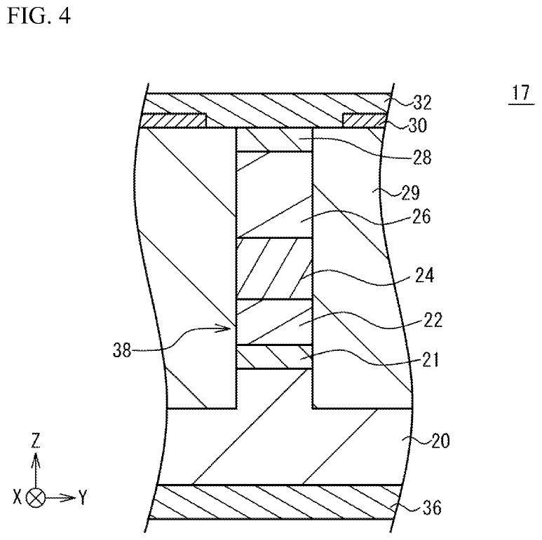

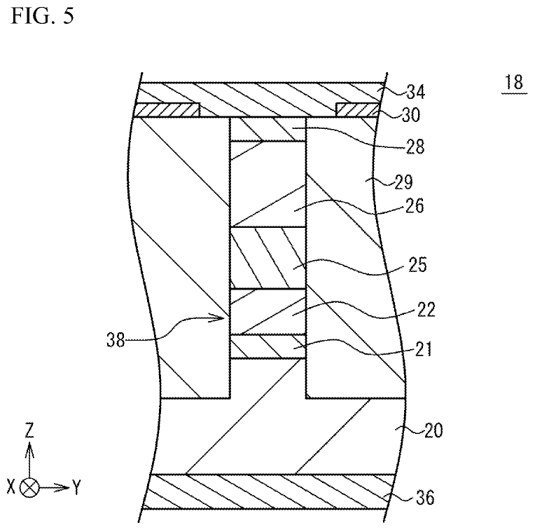

FIG. 3 is an enlarged view of the gain region 17 and the wavelength control region 18. FIG. 4 is a cross-sectional view taken along line B-B of FIG. 3 and illustrates the gain region 17. FIG. 5 is a cross-sectional view taken along line C-C in FIG. 3 and illustrates the wavelength control region 18. A length L1 in the X-axis direction of one gain region 17 illustrated in FIG. 3 is 40 μm, for example. A length L2 in the X-axis direction of one wavelength control region 18 is equal to L1, for example, and is 40 μm.

As illustrated in FIG. 2, the variable-wavelength laser 100 includes a substrate 20, a buffer layer 21, a diffraction grating layer 22, an active layer 24, a wavelength control layer 25, a cladding layer 26, and a contact layer 28. As illustrated in FIGS. 2 to 4, in the gain region 17, the substrate 20, the buffer layer 21, the diffraction grating layer 22, the active layer 24, the cladding layer 26, and the contact layer 28 are laminated in this order in the Z-axis direction, and a mesa 38 is formed as illustrated in FIG. 4. The mesa 38 protrudes from the substrate 20 in the Z-axis direction and extends in the X-axis direction. The height of the mesa 38 is, for example, 3.6 μm. A portion of the substrate 20 other than the mesa 38 is recessed by 1.4 μm, for example, compared to a portion included in the mesa 38. A width of the mesa 38 in the Y-axis direction is, for example, 1.3 μm. Buried layers 29 are provided on both sides of the mesa 38 in the Y-axis direction. An optical confinement layer (not illustrated) is provided between the active layer 24 and the diffraction grating layer 22. An optical confinement layer (not illustrated) is provided between the active layer 24 and the cladding layer 26.

As illustrated in FIGS. 2, 3 and 5, in the wavelength control region 18, the substrate 20, the buffer layer 21, the diffraction grating layer 22, the wavelength control layer 25, the cladding layer 26, and the contact layer 28 are laminated in this order in the Z-axis direction, and the mesa 38 is formed as illustrated in FIG. 5. The buried layers 29 are provided on both sides of the mesa 38 in the Y-axis direction. Cladding layers (not illustrated) may be provided between the active layer 24 and the wavelength control layer 25 and the diffraction grating layer 22.

As illustrated in FIG. 2, the contact layer 28 of the wavelength control region 18 is separated from the contact layer 28 of the gain region 17 at an interval of 5 μm, for example. The active layer 24 and the wavelength control layer 25 are positioned at the same height in the Z-axis direction and are adjacent to each other in the X-axis direction. The active layer 24 of the gain region 17 and the wavelength control layer 25 of the wavelength control region 18 form the optical waveguide 11 of FIG. 1.

An insulating film 30 is provided on the plurality of gain regions 17 and the plurality of wavelength control regions 18, and covers the contact layer 28. The insulating film 30 has openings on the plurality of gain regions 17 and the plurality of wavelength control regions 18, respectively. The contact layer 28 is exposed from the opening.

As illustrated in FIG. 1, the electrodes 32 and 34 are provided on the upper surface of the variable-wavelength laser 100. As illustrated in FIG. 2, the electrode 32 (first electrode) is in contact with an upper surface of the contact layer 28 in the plurality of gain regions 17. The electrode 34 (second electrode) is in contact with the upper surface of the contact layer 28 in the plurality of wavelength control regions 18. The electrode 32 is separated from the electrode 34 at an interval of 7 μm, for example. The electrode 36 is provided on a lower surface of the substrate 20 as illustrated in FIG. 2 and extends to the plurality of gain regions 17 and the plurality of wavelength control regions 18, and also extends to the VOA12, the MOD14 and the SOA16 of FIG. 1.

The substrate 20 is formed of an n-type indium phosphide (InP), for example. The buffer layer 21 is formed of, for example, n-type InP having a thickness of 93 nm. The n-type semiconductor layer is doped with, for example, tin (Sn) or sulfur(S). A cladding layer (not illustrated) of n-type InP may be provided between the active layer 24, the wavelength control layer 25 and the diffraction grating layer 22.

The active layer 24 has a multi-quantum well (MQW) structure. A PL (Photoluminescence) wavelength of the active layer 24 is, for example, 1520 nm. The active layer 24 includes, for example, 10 well layers and 10 barrier layers. The well layers and the barrier layers are alternately laminated in the Z-axis direction. The well layer is formed of indium gallium arsenide phosphorus (InGaAsP) having a compressive strain of 0.6% and a thickness of 5.1 nm, for example. The barrier layer is formed of InGaAsP having a thickness of 10 nm, for example, and has a band gap corresponding to a PL wavelength of 1.3 μm (Q1.3). Hereinafter, in the description of a quaternary compound semiconductor material, the quaternary compound semiconductor material is described in a way including its PL wavelength (Q “PL wavelength”). For example, in the case of a quaternary compound semiconductor with a PL wavelength of 1.3 μm, (Q1.3) is described.

An optical confinement layer (Q1.15) having a thickness of 50 nm is provided between the active layer 24 and the diffraction grating layer 22. An optical confinement layer (Q1.15) having a thickness of 50 nm is provided between the active layer 24 and the cladding layer 26.

The wavelength control layer 25 is a layer in which the refractive index changes by the injection of a current. It is preferable that the change in gain and loss due to the current injection is small with respect to light having the oscillation wavelength. The wavelength control layer 25 may be a bulk layer or may have a multiple quantum well structure, and is formed of, for example, InGaAsP or aluminum gallium indium arsenic (AlGaInAs) of Q1.44. The PL wavelength of the wavelength control layer 25 is shorter than, for example, the oscillation wavelength by 75 nm or more. The thickness of the wavelength control layer 25 is, for example, 212 nm. The refractive index of the wavelength control region 18 can also be changed by controlling a temperature with a heater made of titanium (Ti), for example. In this case, a heater element is provided in place of the electrode 34 in the region.

The buried layer 29 is formed of semi-insulating InP doped with iron (Fe), for example. The cladding layer 26 and the contact layer 28 are p-type semiconductor layers doped with, for example, zinc (Zn). The cladding layer 26 is formed of, for example, p-type InP having a thickness of 1.6 μm. The dopant concentration of the cladding layer 26 is, for example, 5×10¹⁷ cm⁻³ or more and 1.5×10¹⁸ cm⁻³ or less. The contact layer 28 is formed of, for example, p-type indium gallium arsenide (InGaAs) and indium gallium arsenide phosphide (InGaAsP). More specifically, the contact layer 28 is formed by laminating an InGaAs layer and an InGaAsP layer. For example, an InGaAsP layer (Q1.08) having a thickness of 50 nm, an InGaAsP layer (Q1.30) having a thickness of 100 nm, and an InGaAs layer having a thickness of 100 nm are stacked in this order from the cladding layer 26 side. The dopant concentrations of these three layers are, for example, 2.0×10¹⁸ cm⁻³ or more, 2.0×10¹⁸ cm⁻³ or more, and 1.0×10¹⁹ cm⁻³ or more, respectively. The variable-wavelength laser 100 may be formed of compound semiconductors other than semiconductors described above.

The insulating film 30 is formed of an insulator such as silicon nitride (SiN) or silicon oxide (SiO₂). The thickness of the insulating film 30 is, for example, 600 nm. The electrodes 32 and 34 are p-type electrodes formed of a multi-layer structure of metal, for example. The electrodes 32 and 34 may have a laminated structure (AuZn/TiW/Au) in which an alloy layer of gold and zinc, an alloy layer of titanium and tungsten, and a layer of gold are laminated in this order from the substrate 20 side, or may have a laminated structure (Ti/Pt/Au) in which titanium, platinum and gold are laminated in this order from the substrate 20 side. The electrode 36 is an n-type electrode formed with a laminated structure (AuGe/Au/Ti/Au) in which an alloy of gold and germanium, gold, titanium, and gold are laminated in order from the substrate 20 side, for example.

As illustrated in FIG. 2, the diffraction grating layer 22 has a plurality of regions 40 (first region), a plurality of regions 42 (second region), and one region 43. The region 43 is located, for example, at the center of the variable-wavelength light source 10 in the X-axis direction. The region 43 is a λ/4 phase shift region having no diffraction grating 23 described later. The region 43 may be provided at a position other than the center in the X-axis direction of the variable-wavelength light source 10. The region 43 may be a λ/6 phase shift region.

As illustrated in FIGS. 2 and 3, in the gain region 17, the diffraction grating layer 22 has the region 40 and the regions 42. In the X-axis direction, the region 40 occupies the center of the gain region 17. The regions 42 are adjacent to the region 40 in the X-axis direction and located at both ends of the gain region 17 in the X-axis direction. The region 42 extends from a boundary between the gain region 17 and the wavelength control region 18 to the gain region 17 side in the X-axis direction. Further, as illustrated in FIG. 2, among the plurality of gain regions 17, the gain regions 17 located at both ends of the variable-wavelength laser 100 also have the regions 42. The regions 42 are also located at most ends of the gain regions 17. A length L3 in the X-axis direction of one region 42 illustrated in FIG. 3 is, for example, 17.5% of the length L1 of the gain region 17. As an example, the length L1 is 40 μm and the length L3 is 7 μm. In the wavelength control region 18, the diffraction grating layer 22 has the region 40 and does not have the region 42. Although not illustrated, the region 42 may be provided only at one end of the gain region 17 in the X-axis direction. In this case, it is preferable to provide the region 42 aligned with one side of the gain region 17 in the X-axis direction (only the right side or only the left side in the drawing).

The region 40 of the diffraction grating layer 22 includes, for example, an indium gallium arsenide (InGaAsP) layer 22a and an InP layer 22b. The InP layer 22b is an n-type InP layer similar to the buffer layer 21. The InGaAsP layer 22a is strain-free with respect to InP and has a band gap corresponding to a PL wavelength of 1150 nm (Q1.15). The refractive index of the InGaAsPlayer 22a is different from that of the InP layer 22b. The plurality of InGaAsP layers 22a and the plurality of InP layers 22b are alternately arranged periodically along the X-axis direction. A portion where the plurality of InGaAsP layers 22a and the plurality of InP layers 22b are arranged functions as a diffraction grating 23. That is, the region 40 of the diffraction grating layer 22 has the diffraction grating 23. A period (pitch) of the diffraction grating 23 is constant, for example, 236.9 nm.

On the other hand, the region 42 of the diffraction grating layer 22 is formed of the InGaAsP layer 22a and does not include the InP layer 22b. In the region 42, the InGaAsP layer 22a and the InP layer 22b are not arranged periodically, and only the InGaAsP layer 22a is provided. That is, the region 42 does not have the diffraction grating 23. That is, the diffraction gratings 23 are not provided at both ends of the gain region 17. The diffraction gratings 23 are provided on the central side of the gain region 17 and in the wavelength control region 18. The region 42 may be formed of only the InP layer 22b in place of the InGaAsP layer 22a.

A coupling coefficient κ of the diffraction grating 23 is 71 cm⁻¹, for example. A length of the diffraction grating 23 in the entire variable-wavelength light source 10 is 422 μm. The product of the coupling coefficient κ and the length (the normalized coupling coefficient) is about 3.0.

The variable-wavelength light source 10 functions as a distributed feedback (DFB) laser. The active layer 24 has an optical gain. The electrodes 32 and 36 are used to inject the current into the active layer 24 of the gain region 17 and produce light. Light propagates in the X-axis direction and is oscillated at a specific wavelength by the diffraction grating 23 of the diffraction grating layer 22. The electrodes 34 and 36 are used to inject the current into the wavelength control layer 25 of the wavelength control region 18, thereby changing the refractive index of the wavelength control region 18 and changing the oscillation wavelength. The VOA 12 can attenuate light, the MOD14 can modulate light, and the SOA16 can amplify light.

### (Manufacturing Method)

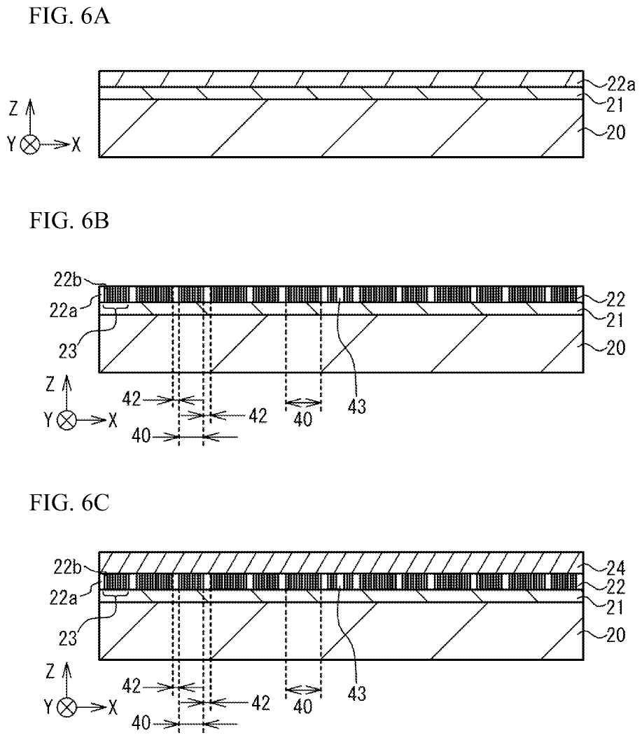

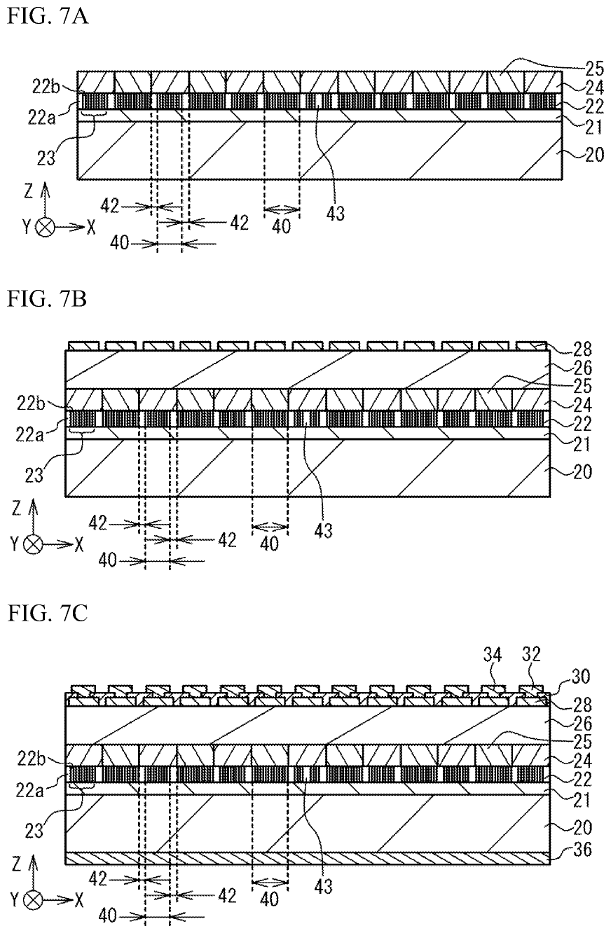

FIGS. 6A to 7C are cross-sectional views illustrating a method of manufacturing the variable-wavelength laser 100, and illustrate cross-sections of the variable-wavelength light source 10 of the variable-wavelength laser 100 corresponding to FIG. 2.

As illustrated in FIG. 6A, the buffer layer 21 and the InGaAsP layer 22a are epitaxially grown on an upper surface of the substrate 20 by, for example, a metal organic chemical vapor deposition (MOCVD) method.

A mask (not illustrated) is formed on the InGaAsP layer 22a by electron beam drawing, photolithography, or the like. By etching the InGaAsP layer 22a using a mask, a plurality of openings are formed in the InGaAsP layer 22a. The plurality of openings are arranged periodically in the X-axis direction. As illustrated in FIG. 6B, the InP layer 22b is epitaxially grown in the opening to form the diffraction grating layer 22. The region 40 is formed in a portion where the InGaAsP layer 22a and the InP layer 22b are arranged. The region 42 is formed in a portion where the InP layer 22b is not buried. The mask is removed.

As illustrated in FIG. 6C, the active layer 24 and the optical confinement layer are epitaxially grown on the diffraction grating layer 22. The active layer 24 is etched periodically along the X-axis direction. As illustrated in FIG. 7A, the wavelength control layer 25 is epitaxially grown. The remaining active layer 24 and the grown wavelength control layer 25 are arranged side by side.

As illustrated in FIG. 7B, the cladding layer 26 and the contact layer 28 are epitaxially grown in order on upper surfaces of the active layer 24 and the wavelength control layer 25. The mesa 38 illustrated in FIGS. 4 and 5 is formed by etching from the contact layer 28 to the middle of the substrate 20 in the Z-axis direction. The buried layer 29 is epitaxially grown on the etched portion.

As illustrated in FIG. 7C, the insulating film 30 is formed on the upper surface of the contact layer 28 by, for example, a plasma CVD method or the like. The plurality of openings are formed in the insulating film 30. The electrodes 32 and 34 are formed on the contact layer 28 and the insulating film 30 by vacuum deposition, lift-off, or the like. The electrode 36 is formed on the lower surface of the substrate 20. The variable-wavelength laser 100 is formed by the above steps.

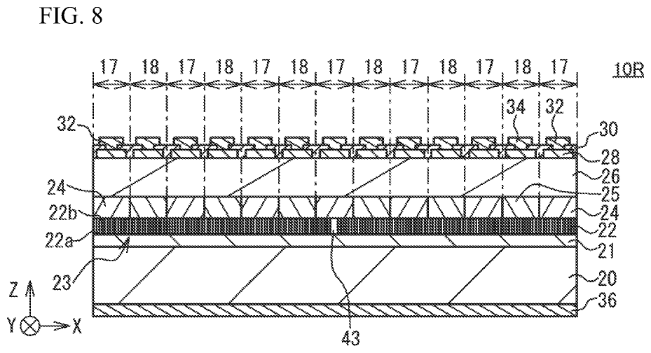

FIG. 8 is a cross-sectional view illustrating a variable-wavelength laser according to a comparative example, and illustrates a cross-section of a variable-wavelength light source 10R similar to FIG. 2. The diffraction grating layer 22 in the comparative example does not have the region 42. In the diffraction grating layers 22, diffraction gratings 23 are provided at the center and both ends in the X-axis direction of the gain region 17 and at the center and both ends of the wavelength control region 18. The coupling coefficient κ of the diffraction grating 23 is 58 cm⁻¹, for example. The product of the coupling coefficient κ and the length of the diffraction grating 23 (e.g. 422 μm) is about 3.0. Other configurations are the same as those of the first embodiment.

### (Reflectance)

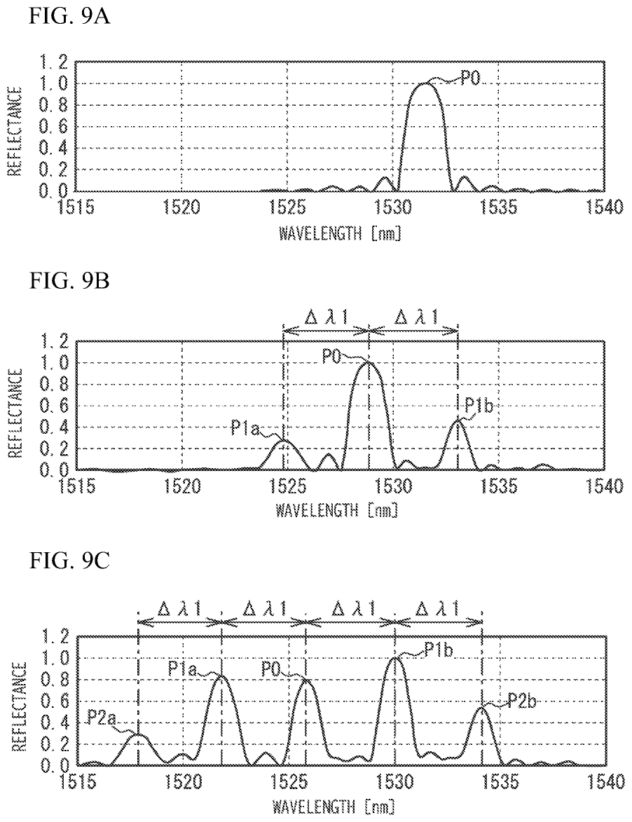

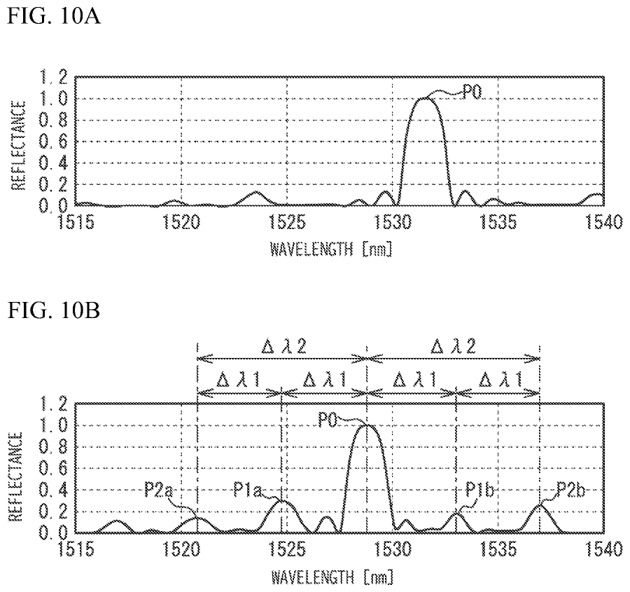

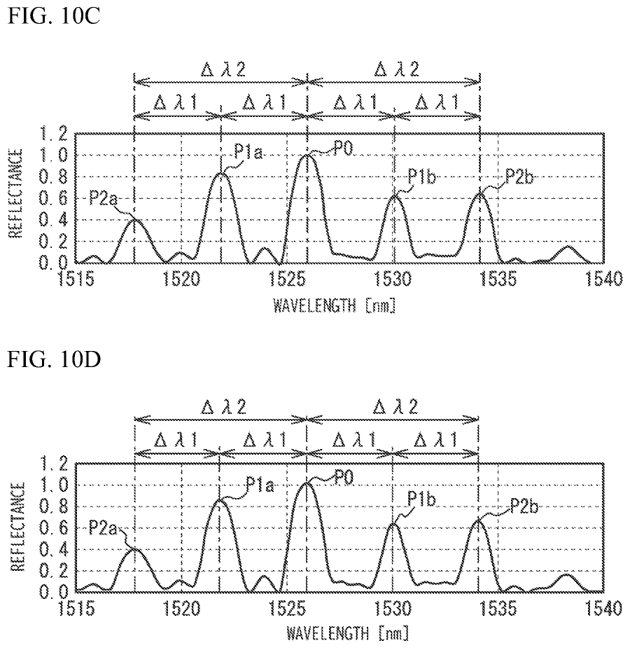

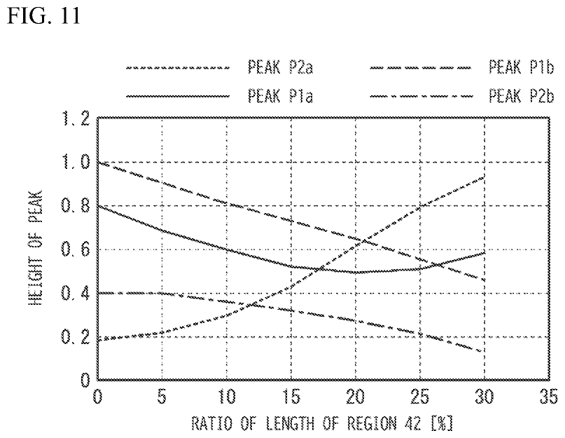

FIGS. 9A to 10D are spectra of reflectances. A horizontal axis represents the wavelength of light. A vertical axis represents the reflectance of light. The reflectance is the product of a reflectance when light travels from a reference position (for example, region 43) to one side in the X-axis direction (for example, a left side in FIG. 2) and returns to the reference position, and a reflectance when light travels from the reference position to the other side in the X-axis direction (for example, a right side in FIG. 2) and returns to the reference position. The laser beam oscillates at a wavelength in which the reflectance becomes 1.

FIGS. 9A to 9C illustrate the reflectances in the comparative example. In the example of FIG. 9A, no current is injected into the wavelength control region 18. In the example of FIG. 9A, the reflectance becomes 1 at a wavelength of about 1532 nm. That is, the oscillation wavelength is about 1532 nm. A peak of the reflectance at the oscillation wavelength is defined as a peak P0. The reflectances at other wavelengths are lower than the peak P0.

An example illustrated in FIG. 9B is an example in which a refractive index of the wavelength control region 18 is reduced by 0.4% by injecting the current into the wavelength control region 18 as compared with a case in which no current is injected. The peak P0 is shifted about 2.8 nm from the wavelength of FIG. 9A to a short wavelength side. A shift amount is determined by the product of a ratio of the length of the wavelength control region 18 to a sum of the length of the gain region 17 and the length of the wavelength control region 18 and a rate of change of the refractive index. A peak P1a occurs at a wavelength separated from the peak P0 by a wavelength interval Δλ1 on the short wavelength side. A peak P1b occurs at a wavelength separated from the peak P0 by the wavelength interval Δλ1 on a long wavelength side. The peak P0 is the largest in the peaks P0, P1a and P1b. The oscillation wavelength in FIG. 9B is the wavelength of peak P0.

An example illustrated in FIG. 9C is an example in which the refractive index of the wavelength control region 18 is reduced by −0.8% by injecting the current into the wavelength control region 18 as compared with the case in which no current is injected. The peak P0 is shifted by about 5.6 nm from the wavelength of FIG. 9A to the shorter wavelength side. In addition to peak P0, peaks P1a and P1b and peaks P2a and P2b occur. A peak P1a occurs at a wavelength separated from the peak P0 by the wavelength interval Δλ1 on the short wavelength side. A peak P2a occurs at a wavelength separated from the peak P1a by the wavelength interval Δλ1 on the short wavelength side. A peak P1b occurs at a wavelength separated from the peak P0 by the wavelength interval Δλ1 on the long wavelength side. A peak P2b occurs at a wavelength separated from the peak P1b by the wavelength interval Δλ1 on the long wavelength side. The peak P1b is the largest in the five peaks. A mode hop occurs in which the oscillation wavelength changes from the wavelength of peak P0 to the wavelength of peak P1b. Thus, in the comparative example, when the refractive index of the wavelength control region 18 is changed, the mode hop occurs. Therefore, it becomes difficult to oscillate light at a desired wavelength.

FIGS. 10A to 10D illustrate spectra according to the first embodiment. The length of one region 42 is 7 μm. The length of one region 42 corresponds to 17.5% of the total length of one gain region 17. In the example of FIG. 10A, no current is injected into the wavelength control region 18. In FIG. 10A, the reflectance exhibits the peak P0 at a wavelength of about 1532 nm, similar to FIG. 9A. That is, light oscillates at the wavelength of about 1532 nm.

In an example of FIG. 10B, the refractive index of the wavelength control region 18 is reduced by −0.4% by injecting the current into the wavelength control region 18 as compared with the case where no current is injected. The peak P0 is shifted about 2.8 nm from the wavelength of FIG. 10A to the short wavelength side. The peak P1a occurs at a wavelength separated from the peak P0 by the wavelength interval Δλ1 on the short wavelength side. The peak P1b occurs at a wavelength separated from the peak P0 by the wavelength interval Δλ1 on the long wavelength side. The peak P2a occurs at a wavelength separated from the peak P0 by a wavelength interval Δλ2 on the short wavelength side and from the peak P1a by the wavelength interval Δλ1 on the short wavelength side. The peak P2b occurs at a wavelength separated from the peak P0 by the wavelength interval Δλ2 on the long wavelength side and from the peak P1b by the wavelength interval Δλ1 on the long wavelength side.

The peak P2a is the smallest in the five peaks. The peak P1a in FIG. 10B has the same magnitude as the peak peak P1a in FIG. 9B. The peak P1b in FIG. 10B is smaller than peak P1b in FIG. 9B. The peak P0 is the largest in the five peaks P1a, P1b, P2a, P2b, and P0.

In an example of FIG. 10C, the refractive index of the wavelength control region 18 is reduced by 0.7% by injecting the current into the wavelength control region 18 as compared with the case where no current is injected into the wavelength control region 18. In an example of FIG. 10D, the refractive index of the wavelength control region 18 is reduced by 0.8% as compared with the case where no current is injected. The peak P0 is shifted about 5.6 nm from the wavelength of FIG. 10A to the short wavelength side. Also in the example of FIG. 10C and the example of FIG. 10D, the peaks peak P1a and P1b occur at wavelengths separated by Δλ1 from peak P0, and the peaks P2a and P2b occur at wavelengths separated by Δλ2 from peak P0. The peak P0 is the largest in the five peaks P1a, P1b, P2a, P2b, and P0. The peak P1b in FIG. 10D is smaller than peak P1b in FIG. 9C.

In any of the examples of FIGS. 10B to 10D, the peak P0 is the largest in the five peaks P1a, P1b, P2a, P2b, and P0. In FIGS. 10B to 10D, the mode hop is suppressed and light can oscillate at the wavelength of peak P0. On the other hand, when the refractive index of the wavelength control region 18 is reduced by 0.9% or more, the peak peak P1a is larger than the peak P0, and the mode hop may occur on the short wavelength side.

FIG. 11 is a diagram illustrating a relationship between the length of the region 42 and the heights of unnecessary sub-peaks other than the target peak P0. A horizontal axis represents a ratio of the length of one region 42 to that of one wavelength control region 18. A vertical axis represents the height (reflectance) of the sub-peak. A dotted line represents the height of the peak P2a. A solid line represents the height of the peak P1a. A dashed line represents the height of peak P1b. A long dashed short dashed line represents the height of the peak P2b. The magnitude of the peak P1b when the region 42 is not provided (the length of the region 42 is 0) is set to 1. In an example of FIG. 11, the refractive index of the wavelength control region 18 is reduced by −0.7% by injecting the current into the wavelength control region 18 as compared to the refractive index when the current is not injected. The product of the length of the variable-wavelength light source 10 and the coupling coefficient of the diffraction grating 23 is 3.0.

By this disclosure, the sub-peaks P1a, P1b, and P2b begin to decrease when the ratio of the length of the region 42 is greater than 0. The sub-peak P2a gradually increases as the ratio of the length of the region 42 becomes greater than 0. However, in a region where the ratio of the length of the region 42 is close to 0, the sub-peak P2a is suppressed sufficiently small. In a region where the ratio of the length of the region 42 is 5%, all of the sub-peaks P1a, P1b, P2a and P2b are suppressed to be small, and the oscillation by the peak P0 becomes predominant. When the ratio of the length of the region 42 is larger than 30%, the sub-peak P2a exceeds 0.9, and when the ratio is 35%, the sub-peak P2a approaches 1. In this case, oscillation by the sub-peak P2a may occur in place of the peak P0. Therefore, a preferred range of the ratio of the length of the region 42 according to the present disclosure is 5% or more and 30% or less. A preferred ratio of the region 42 to the gain region 17 changes depending on the magnitude of the refractive index applied to the wavelength control region 18. When the refractive index applied to the wavelength control region 18 is reduced by 0.7% or less as compared with the refractive index when no current is injected, the above-mentioned ratio is 5% or more and 30% or less. When the refractive index of the wavelength control region 18 is reduced by 0.8% or more as compared with the refractive index when no current is injected, the above-mentioned ratio is 15% or more and 20% or less.

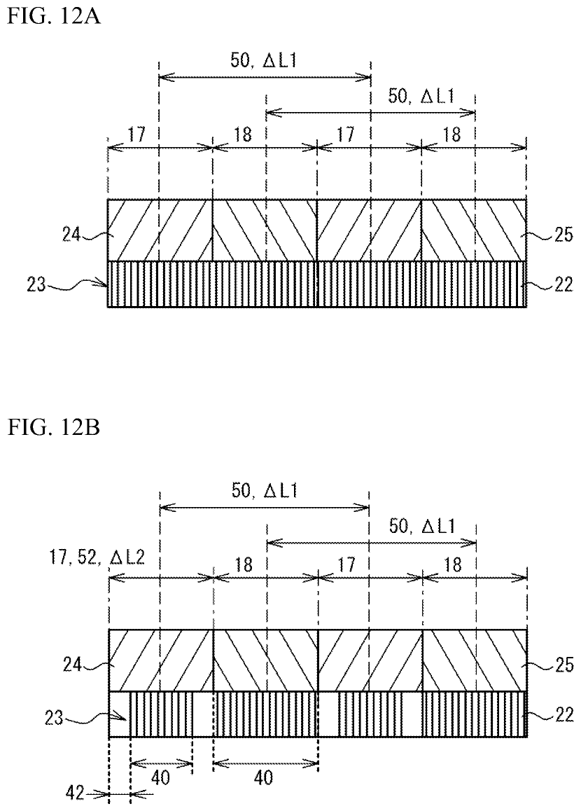

FIGS. 12A and 12B are enlarged views of the diffraction grating layer 22, the active layer 24 and the wavelength control layer 25. FIG. 12A illustrates a comparative example. FIG. 12B illustrates a first embodiment.

When no current is injected into the wavelength control region 18, the refractive index of the wavelength control region 18 is equal to the refractive index of the gain region 17. The reflection characteristics and transmission characteristics of the wavelength control region 18 are equal to the reflection characteristics and transmission characteristics of the gain region 17. The oscillation wavelength of the light is determined by the reflection characteristics and the transmission characteristics of the gain region 17 and the wavelength control region 18. As illustrated in FIGS. 9A and 10A, the laser light oscillates at the wavelength of the peak P0. No sub-peak occurs.

When the current is injected into the wavelength control region 18, the refractive index of the wavelength control region 18 becomes lower than that of the gain region 17. The gain regions 17 having a high refractive index and the wavelength control regions 18 having a low refractive index are arranged periodically along the X-axis direction, so that a periodic structure 50 is formed as illustrated in FIGS. 12A and 12B. The periodic structures 50 are formed from the center of one gain region 17 to the center of the nearest gain region 17 and from the center of one wavelength control region 18 to the center of the nearest wavelength control region 18. A length ΔL1 of the periodic structure 50 is equal to the sum of the length of one gain region 17 and one wavelength control region 18, and is, for example, 80 μm.

For every period ΔL1 of the periodic structure 50, the reflectance of light changes. For example, it is assumed that a Bragg wavelength of the gain region 17 is 1531 nm. When the refractive index of the wavelength control region 18 is reduced by 0.4% with respect to the refractive index of the gain region 17, the Bragg wavelength of the wavelength control region 18 is 1524.9 nm. Light having a wavelength of 1531 nm is strongly reflected each time it passes through the gain region 17. Light having a wavelength of 1524.9 nm is strongly reflected every time it passes through the wavelength control region 18. For each period ΔL1 of the periodic structure 50, the intensity of the Bragg reflection changes.

Since the periodic structure 50 functions as a resonator, the sub-peak occurs. A wavelength interval Δλ between a wavelength λ of the optical mode and a wavelength of a mode (sub-peak) adjacent to the optical mode is determined by the following equation (1). ΔL is a period of the periodic structure. An “n” is an effective refractive index of the variable-wavelength laser 100.

$$Δ λ = λ {0}^{2} / 2 n Δ L \qquad ( 1 )$$

The wavelength interval Δλ1 obtained by substituting λ0=1532 nm, n=3.5, and ΔL1=80 μm into the equation (1) is 4.2 nm. When λ0 is the wavelength of the peak P0, light resonates at a wavelength separated from the peak P0 by the wavelength interval Δλ1, and the sub-peak occurs. When λ0 is the wavelength of the sub-peak, another sub-peak occurs at a wavelength separated from the sub-peak by the wavelength interval Δλ1. In an example of FIG. 9B, the periodic structure 50 generates two sub-peaks (peaks P1a and P1b) adjacent to peak P0. In an example of FIG. 9C, the periodic structure 50 generates four sub-peaks (peaks P1a, P1b, P2a and P2b).

As illustrated in FIG. 12B, also in the first embodiment, the periodic structure 50 is formed by changing the refractive index of the wavelength control region 18. The diffraction grating layer 22 has the regions 42 at both ends of each of the plurality of gain regions 17. The diffraction grating 23 is not provided in the region 42. A periodic structure 52 is formed from one region 42 to the nearest region 42. The length of the periodic structure 52 (period ΔL2) is equal to the length L1 of one gain region 17 and about half the length ΔL1 of the periodic structure 50. The wavelength interval Δλ2 is calculated by substituting the length ΔL2 of the periodic structure 52 into Equation (1). The wavelength interval Δλ2 is about twice of the wavelength interval Δλ1 and is 80 nm.

According to the inventor's estimation based on the implementation results, the peaks P2a and P2b separated from the peak P0 by the wavelength interval 422 are affected by both of the resonance of the periodic structure 50 and the resonance of the periodic structure 52. A resonance mode of the periodic structure 52 is in phase with a resonance mode of the periodic structure 50. Therefore, the peaks P2a and P2b in FIGS. 10B to 10D are larger than the corresponding peaks of the comparative example. On the other hand, with respect to the peaks peak P1a and P1b separated from the peak P0 by the wavelength interval Δλ1, the resonance mode of the periodic structure 52 is opposite in phase to the resonance mode of the periodic structure 50. Therefore, in the first embodiment, the resonance modes (peaks P1a and P1b) of the periodic structure 50 are suppressed.

According to the first embodiment, the variable-wavelength laser 100 has the plurality of gain regions 17 and the plurality of wavelength control regions 18. The diffraction grating layer 22 has the region 40 in the wavelength control region 18. That is, the diffraction grating 23 is provided in the wavelength control region 18. The diffraction grating layer 22 has regions 42 at both ends of the gain region 17. That is, the diffraction gratings 23 are not provided at both ends of the gain region 17. As illustrated in FIGS. 10B to 10D, the sub-peaks can be suppressed low and the mode hop can be suppressed. By changing the refractive index of the wavelength control region 18, the wavelength of the peak P0 can be changed and the laser light can be oscillated at the wavelength of the peak P0.

Even when the diffraction gratings 23 are not provided at both ends of a part of the plurality of gain regions 17, the sub-peaks can be suppressed. As illustrated in FIG. 2, the diffraction grating layer 22 preferably has the regions 42 at both ends of each of the plurality of gain regions 17. That is, the diffraction gratings 23 are not provided at both ends of each of the plurality of gain regions 17. It is possible to suppress sub-peaks effectively and to oscillate at a desired wavelength. Preferably, the number of the regions 42 is 70% or more of the total number of boundaries between the gain region 17 and the wavelength control region 18.

The ratio of the length of one region 42 to the length of one gain region 17 may be, for example, 5% or more and 30% or less, or may be, for example, 10% or more and 25% or less. The reflectance of each sub-peak can be sufficiently reduced by bringing the ratio of the length of the region 42 closer to 17.5%.

The diffraction grating layer 22 includes the InGaAsP layers 22a and the InP layers 22b. The plurality of InGaAsP layers 22a and the plurality of InP layers 22b are alternately arranged in the X-axis direction to form the diffraction grating 23 in the region 40. In the region 42, the InP layer 22b is not provided, but the InGaAsP layer 22a is provided. Therefore, the diffraction grating 23 is not formed in the region 42. The diffraction grating layer 22 may include a semiconductor layer other than the InGaAsP layer 22a and the InP layer 22b. The diffraction grating 23 is formed by alternately arranging two semiconductor layers having different refractive indices.

The diffraction grating layer 22 may be provided between the buffer layer 21, and the active layer 24 and the wavelength control layer 25, or between the cladding layer 26, and the active layer 24 and the wavelength control layer 25.

The electrode 32 is provided in the gain region 17. Tha electrode 34 is provided in the wavelength control region 18. Current can be injected into the gain region 17 and the wavelength control region 18 independently of each other. Light is emitted from the gain region 17. By changing the refractive index of the wavelength control region 18, the wavelength of light is controlled. The number of gain regions 17 may be seven or less, or seven or more. The number of wavelength control regions 18 may be six or less, or six or more. The length L1 of the gain region 17 may be equal to or different from the length L2 of the wavelength control region 18. For example, the lengths L1 and L2 may both be 40 μm. For example, the length L1 may be 35 μm, and the length L2 may be 45 μm.

The variable-wavelength laser 100 is an integrated laser element including the variable-wavelength light source 10, the VOA 12, the MOD 14, and the SOA 16. The light emitted from the variable-wavelength light source 10 can be attenuated, modulated, and amplified. The variable-wavelength laser 100 can oscillate at a wavelength of 1532 nm to 1537.6 nm, for example, and can be applied to a wavelength division multiplex communication system. The variable-wavelength laser 100 may include the variable-wavelength light source 10 without at least one of the VOA 12, the MOD 14, and the SOA 16.

### Second Embodiment

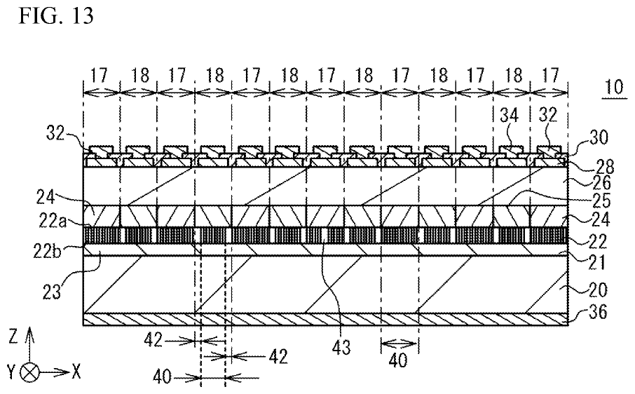

FIG. 13 is a cross-sectional view illustrating the variable-wavelength light source 10 and illustrates a cross-section corresponding to FIG. 2. As illustrated in FIG. 13, the diffraction grating layer 22 in the second embodiment has the region 40 and does not have the region 42 in the gain region 17. The diffraction grating layer 22 has the region 40 at the center of the wavelength control region 18 in the X-axis direction, and has the regions 42 at both ends of the region. That is, the diffraction grating 23 is provided at the center side of the wavelength control region 18, and the diffraction gratings 23 are not provided at both ends thereof. The length of one region 42 is, for example, 17.5% of the length of the wavelength control region 18. The n-type buffer layer 21 has a thickness of 98 nm, for example. The coupling coefficient κ of the diffraction grating 23 is, for example, 69 cm⁻¹. The product of the coupling coefficient κ and the length of the diffraction grating 23 (e.g., 436 μm) is about 3.0. Other configurations are the same as those of the first embodiment. Although not illustrated, the region 42 may be located only at one end of the wavelength control region 18 in the X-axis direction. In this case, it is desirable that the region 42 is aligned and located at one side of the wavelength control region 18 in the X-axis direction.

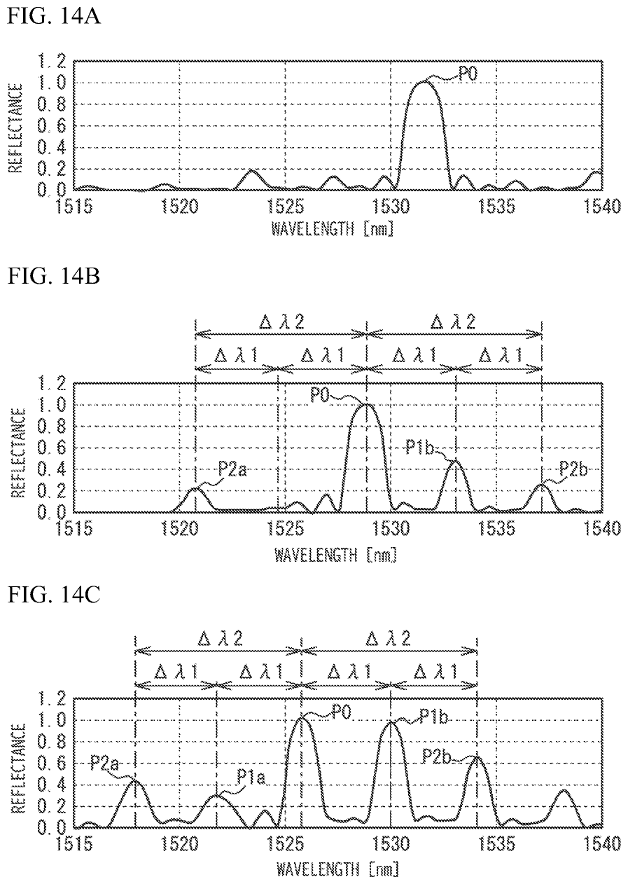

FIGS. 14A to 14C are spectra of reflectances. The length of one region 42 is 7 μm. In the example of FIG. 14A, no current is injected into the wavelength control region 18. In FIG. 14A, the reflectance exhibits the peak P0 at a wavelength of about 1532 nm.

In the example of FIG. 14B, the current is injected into the wavelength control region 18, and the refractive index of the wavelength control region 18 is reduced by −0.4% as compared with the case where no current is injected into the wavelength control region 18. The peak P0 shifts from the wavelength of FIG. 14A to the short wavelength side. In addition to the peak P0, the peaks P1b, P2a and P2b occur. The peak P2a occurs at a wavelength separated from the peak P0 by the wavelength interval Δλ2 on the short wavelength side and from the peak P1a by the wavelength interval Δλ1 on the short wavelength side. The peak P1b occurs at a wavelength separated from the peak P0 by the wavelength interval Δλ1 on the long wavelength side. The peak P2b occurs at a wavelength separated from the peak P0 by the wavelength interval Δλ2 on the long wavelength side and from the peak P1b by the wavelength interval Δλ1 on the long wavelength side. A peak does not occur at a wavelength separated from the peak P0 by the wavelength interval Δλ1 on the short wavelength side. The peak P0 is the largest in the four peaks P1b, P2a, P2b, and P0.

In the example of FIG. 14C, the refractive index of the wavelength control region 18 is reduced by 0.8% as compared with the case where no current is injected. The peak P0 shifts from the wavelength of FIG. 14A to the short wavelength side. The peaks P1a and P1b occur at wavelengths separated from peak P0 by Δλ1, and peaks P2a and P2b occur at wavelengths separated from peak P0 by Δλ2. The peak P0 is the largest in the five peaks P1a, P1b, P2a, P2b, and P0.

In all examples of FIGS. 14A to 14C, the peak P0 is the largest. Even when the refractive index of the wavelength control region 18 is changed to −0.8%, the mode hop is suppressed, and the variable-wavelength laser oscillates at the wavelength of the peak P0. When the refractive index of the wavelength control region 18 is reduced by 0.9% or more, the peak P1b becomes larger than the peak P0, and the mode hop may occur on the long wavelength side.

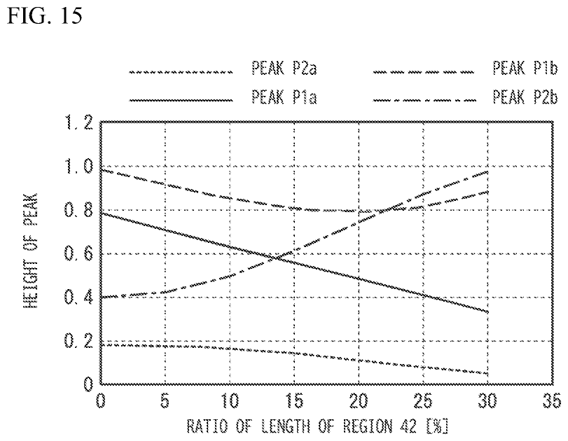

FIG. 15 a diagram illustrating a relationship between the length of the region 42 and the heights of peaks. A horizontal axis represents the ratio of the length of one region 42 to one wavelength control region 18. A vertical axis represents the height (reflectance) of the peak. The refractive index of the wavelength control region 18 is reduced by 0.7% as compared with the refractive index when no current is injected. The product of the length of the variable-wavelength light source 10 and the coupling coefficient of the diffraction grating 23 is 3.0.

When the ratio of the length of the region 42 is greater than 5%, the peaks P1a, P1b and P2a become smaller and the peak P2b becomes larger. In the range of the ratio of the length of the region 42 from 0% to 20%, the peak P1b is the largest in the peaks P1a, P1b, P2a, and P2b. When the ratio of the length is 15%, the magnitude of the peak P1b is reduced to about 0.8. When the ratio of the length is around 15% to 20%, all the peaks are equal to or less than 0.8. When the ratio of the length exceeds 20%, the peak P2b is the largest in the four peaks. When the ratio of the length exceeds 30%, the magnitude of the peak P2b approaches 1 and the mode hop may occur. In order to suppress the sub-peaks P1a, P1b, P2a and P2b and to suppress the mode hop, the ratio of the length of the region 42 is preferably 5% or more and 30% or less, for example.

According to the second embodiment, the diffraction grating layer 22 has the region 40 in the gain region 17. That is, the diffraction grating 23 is provided in the gain region 17. The diffraction grating layer 22 has the regions 42 at both ends of the wavelength control region 18. That is, the diffraction gratings 23 are not provided at both ends of the wavelength control region 18. The sub-peaks can be suppressed low, and the mode hop can be suppressed.

Even when the diffraction gratings 23 are not provided at both ends of a part of the plurality of wavelength control regions 18, the sub-peaks can be suppressed. Preferably, the diffraction grating layer 22 has the regions 42 at both ends of each of the plurality of wavelength control regions 18. That is, the diffraction gratings 23 are not provided at both ends of each of the plurality of wavelength control regions 18. It is possible to suppress the sub-peaks effectively and to oscillate at a desired wavelength. For example, the ratio of the number of wavelength control regions 18 having the regions 42 to the number of wavelength control regions 18 is preferably 70% or more.

The preferred ratio of the region 42 to the wavelength control region 18 changes depending on the magnitude of the refractive index applied to the wavelength control region 18. When the refractive index applied to the wavelength control region 18 is reduced by 0.7% or less as compared with the refractive index when no current is injected, the above-mentioned ratio is 5% or more and 30% or less. When the refractive index of the wavelength control region 18 is reduced by 0.8% or more as compared with the refractive index when no current is injected, the above-mentioned ratio is 15% or more and 20% or less. The ratio of the length of one region 42 to the length of one wavelength control region 18 may be, for example, 10% or more and 25% or less. The reflectance of each sub-peak can be sufficiently reduced by bringing the ratio of the length of the region 42 closer to 17.5%.

### Third Embodiment

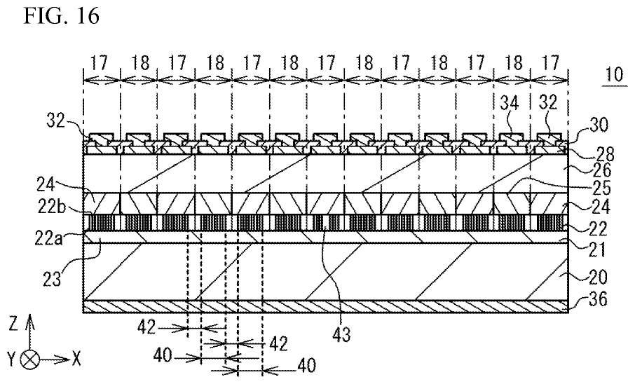

FIG. 16 is a cross-sectional view illustrating the variable-wavelength light source 10, and illustrates a cross-section corresponding to FIG. 2. As illustrated in FIG. 16, the diffraction grating layer 22 in the third embodiment has regions 40 and 42 in the gain region 17 and the wavelength control region 18. The regions 40 are provided at the center side of the gain region 17 and at the center side of the wavelength control region 18. That is, the diffraction gratings 23 are provided at the center side of the gain region 17 and at the center side of the wavelength control region 18. The region 42 extends from an end of one gain region 17 to an end of the adjacent wavelength control region 18 in the X-axis direction. The diffraction gratings 23 are not provided at both ends of the gain region 17 and both ends of the wavelength control region 18. One region 42 occupies a length obtained by adding a length of a predetermined ratio to the length of one gain region 17 in the X-axis direction and a length of a predetermined ratio to the length of one wavelength control region 18. In this embodiment, the predetermined ratio is 17.5%. Further, the ratio of one region 42 to one gain region 17 is equal to the ratio of one region 42 to one wavelength control region 18. Therefore, when the lengths of the gain region 17 and the wavelength control region 18 are different from each other, the center position of the region 42 extending over both the gain region 17 and the wavelength control region 18 is displaced from the boundary between the gain region 17 and the wavelength control region 18. The coupling coefficient κ of the diffraction grating 23 is, for example, 89 cm⁻¹. The product of the coupling coefficient κ and the length of the diffraction grating 23 (e.g., 338 μm) is about 3.0. The n-type buffer layer 21 has a thickness of 51 nm, for example. Other configurations are the same as those of the first embodiment.

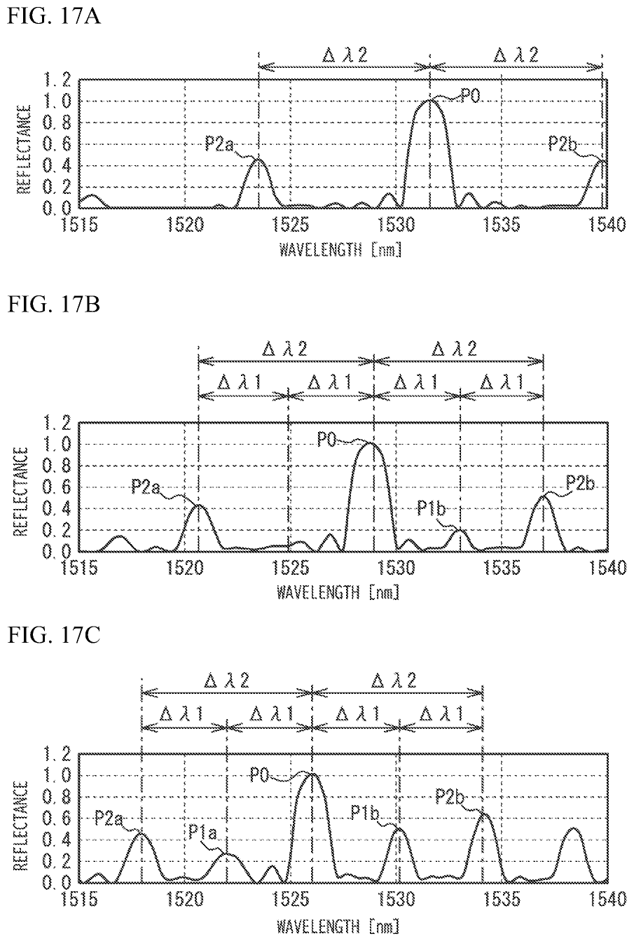

FIGS. 17A to 17C are spectra of reflectances. The length of one region 42 is 7 μm. In an example of FIG. 17A, no current is injected into the wavelength control region 18. In FIG. 17A, the reflectance exhibits the peak P0 at a wavelength of about 1532 nm. The peak P2a occurs at a wavelength separated from the peak P0 by the wavelength interval Δλ2 on the short wavelength side. The peak P2b occurs at a wavelength separated from the peak P0 by the wavelength interval Δλ2 on the long wavelength side. The peak P0 is the largest in the three peaks.

In an example of FIG. 17B, the current is injected into the wavelength control region 18, and the refractive index of the wavelength control region 18 is reduced by 0.4% as compared with the case where no current is injected. The peak P0 shifts from the wavelength of FIG. 17A to the shorter wavelength side. In addition to the peak P0, the peaks P1b, P2a and P2b occur. The peak P1b occurs at a wavelength separated from the peak P0 by the wavelength interval Δλ1 on the long wavelength side. The peak does not occur at a wavelength separated from the peak P0 by the wavelength interval Δλ1 on the short wavelength side. The peak P0 is the largest in the four peaks P1b, P2a, P2b, and P0.

In an example of FIG. 17C, the refractive index of the wavelength control region 18 is reduced by 0.8% as compared with the case where no current is injected. The peak P0 shifts from the wavelength of FIG. 17A to the shorter wavelength side. The peaks peak P1a and P1b occur at wavelengths separated from the peak P1 by Δλ1. The peaks P2a and P2b occur at wavelengths separated from the peak P0 by Δλ2. The peak P0 is the largest in the five peaks P1a, P1b, P2a, P2b, and P0. In all examples of FIGS. 17A to 17C, the peak P0 is the largest. Even when the refractive index of the wavelength control region 18 is changed to −0.8%, the mode hop is suppressed, and the variable-wavelength laser oscillates at the wavelength of the peak P0.

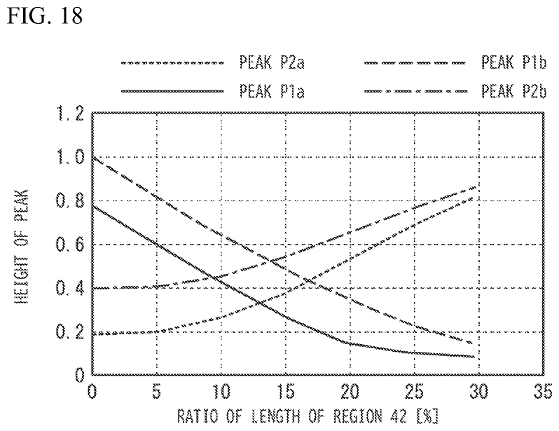

FIG. 18 is a diagram illustrating the relationship between the length of the region 42 and the heights of peaks. A horizontal axis represents the ratio of the length of one region 42 to one wavelength control region 18. A vertical axis represents the height (reflectance) of the peak. The magnitude of the peak P1b when the region 42 is not provided (the length of the region 42 is 0) is set to 1. The refractive index of the wavelength control region 18 is reduced by 0.7% as compared with the refractive index when no current is injected. The product of the length of the variable-wavelength light source 10 and the coupling coefficient of the diffraction grating 23 is 3.0.

The region 42 is a region having a length obtained by adding a length of a predetermined ratio to the length of one gain region 17 in the X-axis direction and a length of a predetermined ratio to the length of one wavelength control region 18. The ratio of the length of the region 42 corresponds to the predetermined ratio multiplied by both the gain region 17 and the wavelength control region 18. As the ratio of the length of the region 42 becomes greater than 5%, the peaks P1a and P1b become smaller and the peaks P2a and P2b become larger. In the range of the ratio of the length of the region 42 from 5% to about 15%, the peak P1b is the largest in the peaks P1a, P1b, P2a and P2b. When the ratio of the length is from 10% to 30%, all the peaks are approximately 0.8 or less. When the ratio of the length is about 15% or more and 20% or less, all peaks are 0.7 or less. When the ratio of the length exceeds 15%, the peak P2b is the largest in the four peaks. When the ratio of the length exceeds 30%, the magnitude of the peaks P2a and P2b approaches 1 and the mode hop may occur. In order to suppress the sub-peaks P1a, P1b, P2a and P2b and to suppress the mode hop to P2a, the ratio of the length of the region 42 is set to 5% or more and 30% or less, for example.

According to the third embodiment, the diffraction grating layer 22 has the regions 42 at both ends of the gain region 17 and at both ends of the wavelength control region 18. That is, the diffraction gratings 23 are not provided at both ends of the gain region 17 and at both ends of the wavelength control region 18. The sub-peaks can be suppressed low, and the mode hop can be suppressed.

Even when the diffraction gratings 23 are not provided at both ends of a part of the plurality of gain regions 17 and at both ends of a part of the plurality of wavelength control regions 18, the sub-peaks can be suppressed. The diffraction grating layer 22 preferably has the regions 42 at both ends of each of the plurality of gain regions 17 and at both ends of each of the plurality of wavelength control regions 18. That is, the diffraction gratings 23 are not provided at both ends of each of the plurality of gain regions 17 and at both ends of each of the plurality of wavelength control regions 18. It is possible to suppress sub-peaks effectively and to oscillate at the desired wavelength. For example, the ratio of the number of the gain regions 17 having the region 42 to the number of the plurality of gain regions 17 is preferably 70% or more. For example, the ratio of the number of the wavelength control regions 18 having the regions 42 to the number of the plurality of wavelength control regions 18 is preferably 70% or more.

The ratio of the length of the above-described region 42 changes depending on the magnitude of the refractive index applied to the wavelength control region 18. When the refractive index applied to the wavelength control region 18 is reduced by 0.7% or less as compared with the refractive index when no current is injected, the ratio of the length is 5% to 30%. When the refractive index of the wavelength control region 18 is reduced by 0.8% or more as compared with the refractive index when no current is injected, the ratio of the length is in the range of 15% to 20%. The ratio of the length of one region 42 to the length of one wavelength control region 18 may be, for example, 10% or more and 25% or less. The reflectance of each sub-peak can be sufficiently reduced by bringing the ratio of the length of the region 42 closer to 17.5%.

As illustrated in FIGS. 2, 13 and 16, the diffraction gratings 23 are not provided at both ends of at least one of the gain region 17 and the wavelength control region 18. The intensity of light at the center of the gain region 17 and the wavelength control region 18 is larger than the intensity at portions other than the center. When the diffraction grating 23 are not provided at the centers of the gain region 17 and the wavelength control region 18, light is hardly reflected by the diffraction grating 23. The diffraction gratings 23 are not provided at both ends of at least one of the gain region 17 and the wavelength control region 18, and the diffraction grating 23 is provided at the center thereof. Light is reflected by the diffraction grating 23, and the variable-wavelength light source 10 can function as a DFB laser. In addition, the sub-peaks can be suppressed.

Although the embodiments of the present disclosure have been described in detail above, the present disclosure is not limited to the specific embodiments, and various modifications and changes can be made within the scope of the gist of the present disclosure described in the claims.

### EXPLANATION OF REFERENCE NUMERALS

10, 10R variable-wavelength light source
11 optical waveguide
12 variable optical attenuator
13, 15, 19, 32, 34, 36 electrode
14 modulator
16 semiconductor optical amplifier
17 gain region
18 wavelength control region
20 substrate
21 buffer layer
22 diffraction grating layer
22a InGaAsP layer
22b InP layer
23 diffraction grating
24 active layer
25 wavelength control layer
26 cladding layer
28 contact layer
29 buried layer
30 insulating film
38 mesa
40, 42, 43 region
50, 52 periodic structure
100 variable-wavelength laser

1. A variable-wavelength laser comprising:
a gain region and a wavelength control region alternately arranged along a propagation direction of light;
a diffraction grating arranged in each of the gain region and the wavelength control region; and
a region located at least one of an end of the gain region and an end of the wavelength control region in a boundary between the gain region and the wavelength control region, the region being without the diffraction grating;
wherein a length of the region without the diffraction grating is 5% or more and 30% or less of a length of the gain region or the wavelength control region to which the region belongs.

2. The variable-wavelength laser according to claim 1, wherein a number of regions without the diffraction grating is 70% or more of a total number of boundaries between the gain region and the wavelength control region.

3. The variable-wavelength laser according to claim 1, wherein the region without the diffraction grating is arranged at a most end of the gain region or the wavelength control region.

4. The variable-wavelength laser according to claim 1, wherein the length of the region without the diffraction grating is 10% or more and 25% or less of the length of the gain region or the wavelength control region to which the region belongs.

5. The variable-wavelength laser according to claim 1, wherein the length of the region without the diffraction grating is 15% or more and 20% or less of the length of the gain region or the wavelength control region to which the region belongs.

6. The variable-wavelength laser according to claim 1, further comprising:
an optical modulator optically coupled to the gain region and the wavelength control region.

7. The variable-wavelength laser according to claim 6, wherein a variable optical attenuator is arranged between the optical modulator, and the gain region and the wavelength control region.

8. The variable-wavelength laser according to claim 6, wherein a semiconductor optical amplifier is arranged at an output of the optical modulator.

9. The variable-wavelength laser according to claim 1, wherein a refractive index of the wavelength control region is controlled by current injection.

10. The variable-wavelength laser according to claim 1, wherein a refractive index of the wavelength control region is controlled by a heater.

11. The variable-wavelength laser according to claim 1, wherein the region without the diffraction grating is arranged at both ends of any one of the gain region and the wavelength control region.

12. The variable-wavelength laser according to claim 1, wherein the region without the diffraction grating is arranged at both ends of both the gain region and the wavelength control region.

13. The variable-wavelength laser according to claim 1, wherein the region without the diffraction grating is arranged only at one end of any one of the gain region and the wavelength control region.
